(19) United States
(12) Patent Application Publication
(10) Pub. No.: US 2007/0001261 A1
(43) Pub. Date: Jan. 4, 2007

(54) Substrate and manufacturing method thereof

(76) Inventor: Koichi Tanaka, Nagano-shi (JP)

Correspondence Address: LADAS & PARRY LLP, 224 SOUTH MICHIGAN AVENUE, SUITE 1600, CHICAGO, IL, 60604, US

(21) Appl. No.: 11/476,231

(22) Filed: Jun. 27, 2006

(30) Foreign Application Priority Data
Jul. 4, 2005 (JP) 2005-195161

(51) Int. Cl. H01L 29/00

(52) U.S. Cl. 257/532

(57) ABSTRACT

A substrate is disclosed that includes a base material, a first capacitor arranged on the base material, and a second capacitor arranged on the base material near the first capacitor. The first capacitor is realized by a lower electrode, a first dielectric layer, and a first upper electrode; and the second capacitor is realized by the lower electrode that is held in common with the first capacitor, a second dielectric layer, and a second upper electrode having a smaller area than the first upper electrode. The first capacitor and the second capacitor are connected in parallel in a case where the capacity of the first capacitor is less than a desired capacity.

### BACKGROUND OF THE INVENTION

1. Field of the Invention

The present invention relates to a substrate including a base material with a capacitor mounted thereon and a method for manufacturing such a substrate.

2. Description of the Related Art

A substrate may include a base material and a capacitor arranged on the base material which capacitor is made of a lower electrode, a dielectric layer, and an upper electrode, for example. In such a substrate, the capacity of the capacitor (e.g., capacity measured by a probe) may not fall within a desired capacity (predetermined capacity value range for a capacitor to be of fair quality) owing to variations in the thickness of the dielectric layer and variations in the area of the upper electrode, for example, and the production yield of the capacitor may be decreased as a result.

It is noted that in a case where the capacity of the capacitor is greater than the desired capacity, laser trimming may be performed on the capacitor.

Laser trimming involves removing a portion of the upper electrode using laser to reduce the area of the upper electrode so that the capacity of the capacitor may conform within the desired capacity (e.g., see Japanese Laid-Open Patent Publication No. 5-347230).

However, since laser output adjustment is quite difficult, the dielectric layer and/or the lower electrode arranged beneath the upper electrode may be damaged by the output laser in a case where laser trimming is used. Also, laser trimming requires a relatively long processing time so that productivity of the substrate may-be decreased.

### SUMMARY OF THE INVENTION

According to an aspect of the present invention, a technique is provided for easily adjusting the capacity of a capacitor of a substrate to fall within a desired capacity without damaging the capacitor or lowering productivity of the substrate.

According to one specific embodiment of the present invention, a substrate is provided that includes:

a base material;

a first capacitor arranged on the base material, the first capacitor being realized by a lower electrode, a first dielectric layer, and a first upper electrode; and

a second capacitor arranged on the base material near the first capacitor, the second capacitor being realized by the lower electrode that is held in common with the first capacitor, a second dielectric layer, and a second upper electrode having a second area that is smaller than a first area of the first upper electrode;

wherein, the first capacitor and the second capacitor are connected in parallel in a case where the capacity of the first capacitor is less than a desired capacity.

According to an aspect of the present embodiment, by arranging the second capacitor on the base material near the first capacitor which second capacitor is realized by the lower electrode that is held in common with the first capacitor, the second dielectric layer, and the second upper electrode having a smaller area than the first upper electrode; and connecting the first capacitor and the second capacitor in parallel when the capacity of the first capacitor is less than the desired capacity, the first capacitor and the second capacitor may realize a single capacitor, and the capacity of the single capacitor realized by the first and second capacitors (e.g., sum of the respective capacities of the first capacitor and the second capacitor) may be easily adjusted to fall within the desired capacity (e.g., predetermined capacity value range for a capacitor to be of fair quality).

According to another specific embodiment of the present invention, a method is provided for manufacturing a substrate that includes a base material, a first capacitor arranged on the base material, and a second capacitor arranged on the base material near the first capacitor, the first capacitor being realized by a lower electrode, a first dielectric layer, and a first upper electrode, and the second capacitor being realized by the lower electrode that is held in common with the first capacitor, a second dielectric layer, and a second upper electrode having a second area that is smaller than a first area of the first upper electrode, the method including:

a first and second capacitor forming step involving simultaneously forming the first capacitor and the second capacitor on the base material;

a capacity measuring step involving measuring a first capacity of the first capacitor and a second capacity of the second capacitor; and

a capacitor connecting step involving connecting the first capacitor and the second capacitor in parallel in a case where the first capacity of the first capacitor is less than a desired capacity.

According to an aspect of the present embodiment, by connecting the first capacitor and the second capacitor in parallel when the capacity of the first capacitor is less than the desired capacity, the first capacitor and the second capacitor may realize a single capacitor, and the capacity of the single capacitor realized by the first and second capacitors (e.g., sum of the respective capacities of the first capacitor and the second capacitor) may be easily adjusted to fall within the desired capacity (e.g., predetermined capacity value range for a capacitor to be of fair quality). Also, since laser trimming is not used in the present embodiment, the first capacitor may be protected from damage, for example. Further capacity adjustment of a capacitor may be performed in a shorter period of time in the present embodiment compared to the case of using the laser trimming method, for example.

### BRIEF DESCRIPTION OF THE DRAWINGS

FIG. 1 is a cross-sectional diagram showing a configuration of a substrate according to an embodiment of the present invention;

FIG. 2 is a plan view of the substrate shown in FIG. 1;

FIG. 3 is a diagram illustrating a first process step of a process for manufacturing the substrate shown in FIG. 1;

FIG. 4 is a diagram illustrating a second process step of a process for manufacturing the substrate shown in FIG.

FIG. 5 is a diagram illustrating a third process step of a process for manufacturing the substrate shown in FIG. 1;

FIG. 6 is a diagram illustrating a fourth process step of a process for manufacturing the substrate shown in FIG.

FIG. 7 is a diagram illustrating a fifth process step of a process for manufacturing the substrate shown in FIG. 1;

FIG. 8 is a diagram illustrating a sixth process step of a process for manufacturing the substrate shown in FIG. 1;

FIG. 9 is a diagram illustrating a seventh process step of a process for manufacturing the substrate shown in FIG. 1;

FIG. 10 is a diagram illustrating an eighth process step of a process for manufacturing the substrate shown in FIG. 1; and

FIG. 11 is a cross-sectional diagram showing a configuration of a substrate in which a first capacitor and a second capacitor are not connected in parallel.

### DETAILED DESCRIPTION OF THE PREFERRED EMBODIMENTS

In the following, preferred embodiments of the present invention are described with reference to the accompanying drawings.

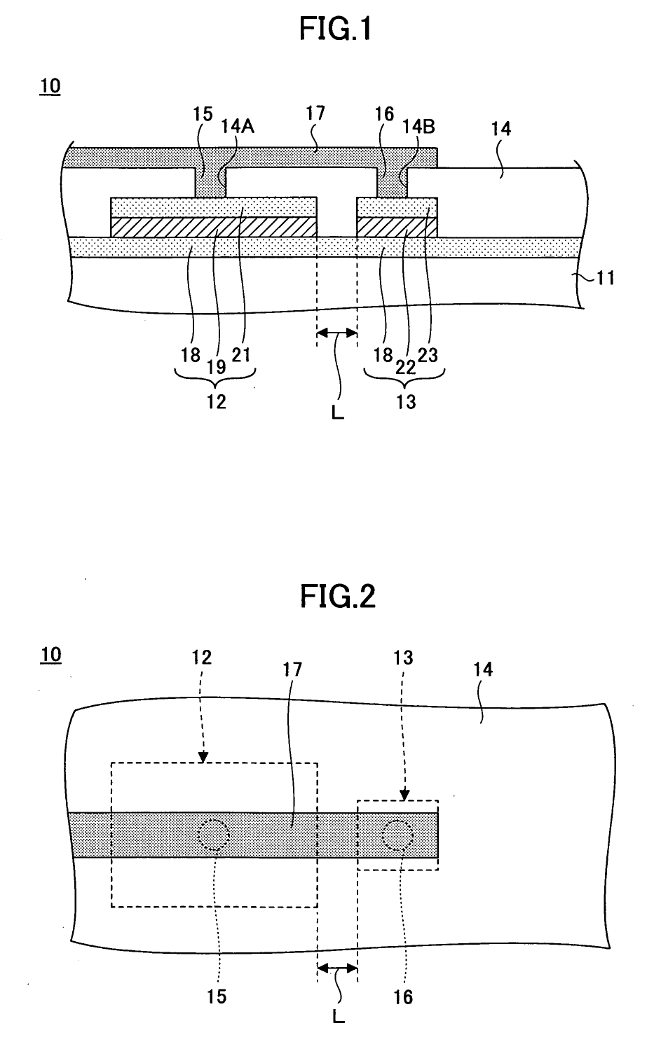

FIG. 1 is a cross-sectional diagram of a substrate according to an embodiment of the present invention. Specifically, FIG. 1 illustrates a substrate 10 that includes a first capacitor 12 having a capacity that is less than a desired capacity. It is noted that in the following descriptions, ‘desired capacity’ refers to a predetermined capacity value range for a capacitor to be of fair quality.

As is shown in FIG. 1, the substrate 10 includes a base material 11, a first capacitor 12, a second capacitor 13, a resin layer 14, vias 15, 16, and wiring 17. It is noted that the substrate 10 may be used as a semiconductor package or an interposer, for example.

The base material 11 may have a buildup layer made of the resin layer 14, the vias 15, 16, and the wiring 17 arranged thereon as is necessary or desired. The first and second capacitors 12 and 13 are arranged on the base material 11. It is noted that the detailed structures of the first and second capacitors 12 and 13 are described below.

The resin layer 14 is arranged to cover the first and second capacitors 12 and 13. The resin layer 14 includes a region on which the wiring 17 is arranged, an opening 14A positioned above the first capacitor 12 of this wiring formation region in which opening 14A the via 15 is formed, and an opening 14B positioned above the second capacitor 13 of the wiring formation region in which opening 14B the via 16 is formed. It is noted that the resin layer 14 may be made of epoxy resin, for example.

The via 15 is formed within the opening 14A of the resin layer 14. The via 15 is configured to realize electrical connection between an upper electrode 21 of the first capacitor 12 and the wiring 17. The via 16 is formed within the opening 14B of the resin layer 14 and is configured to realize electrical connection between an upper electrode 23 of the second capacitor 13 and the wiring 17. It is noted that the vias 15 and 16 may be made of conductive material, for example. In one specific example, Cu may be used as the conductive material of the vias 15 and 16.

FIG. 2 is a plan view of the substrate according to the present embodiment showing a positional relationship between the wiring 17 and the vias 15, 16. As is described above, the wiring 17 is arranged on a portion of the resin layer 14. The wiring 17 is configured to realize electrical connection between the vias 15 and 16 (see FIGS. 1 and 2). The wiring 17 may be made of conductive material, and in one specific example, Cu may be used as the conductive material of the wiring 17.

The first capacitor 12 is realized by a lower electrode 18, a dielectric layer 19, and the upper electrode 21 that are deposited in this order. The lower electrode 18 is arranged on the base material 11. It is noted that the lower electrode 18 functions as a common electrode for the first capacitor 12 and the second capacitor 13. The lower electrode 18 may be made of Au, Al, Pt, Ag, Pd, Cu, or alloys thereof, for example. The thickness of the lower electrode 18 may be 3-70 Am, for example.

The dielectric layer 19 is arranged on the lower electrode 18. The material of the dielectric layer 19 is not limited to a particular type of material and any type of dielectric material may be used. In a preferred embodiment, the dielectric layer 19 may be made of a metal oxide material having a Perovskite crystal structure that has a high dielectric constant. For example, (Ba, Sr)TiO₃(BST), SrTiO₃(ST), BaTiO₃, Ba(Zr, Ti)O₃, Ba(Ti, Sn)O₃, Pb(Zr, Ti)O₃(PZT), (Pb, La)(Zr, Ti)O₃(PLZT), Pb(Mn, Nb)O₃—PbTiO₃(PMN—PT), or Pb(Ni, Nb)O₃—PbTiO₃ may preferably be used as the material of the dielectric layer 19.

In the case of using a metal oxide material having a Perovskite crystal structure as the dielectric layer 19, the lower electrode 18 is preferably made of Pt. Specifically, by using Pt as the lower electrode 18, the dielectric layer 19 may be epitaxially grown, and as a result, the dielectric constant of the dielectric layer 19 may be increased.

The upper electrode 21 is arranged on the dielectric layer 19. The upper electrode 21 may be made of Au, Al, Pt, Ag, Pd, Cu, or alloys thereof, for example. The thickness of the upper electrode may be 3-70 μm, for example.

The area of the upper electrode 21 is preferably arranged such that the center value of actual measurement values of the capacity of the first capacitor 12 is slightly smaller than the center value of the desired capacity for the first capacitor 12. In the case where the capacity of the first capacitor 12 is less than the desired capacity, the first capacitor 12 and the second capacitor 13 may be connected in parallel so that the first capacitor 12 and the second capacitor 13 may realize a single capacitor, and the sum of the capacities of the first capacitor 12 and the second capacitor 13 may be adjusted to fall within the desired capacity.

The second capacitor 13 is arranged on the base material 11 near the first capacitor 12, and is realized by the lower electrode 18, a dielectric layer 22, and an upper electrode 23 that are deposited in this order. The dielectric layer 22 may be made of the same material as the dielectric layer 19, and may be arranged to have the same thickness as the dielectric layer 19. The upper electrode 23 may be made of the same material as the upper electrode 21, and may be arranged to have the same thickness as the upper electrode 21. The first capacitor 12 and the second capacitor 13 are connected in parallel via the lower electrode 18 that is commonly connected to the vias 15, 16, the wiring 17, and the first and second capacitors 12, 13. In this way, the first capacitor 12 and the second capacitor 13 may comprise a single capacitor (referred to as ‘capacitor A’ hereinafter).

In the following descriptions, the capacity of the first capacitor 12 is denoted as capacity C1, the capacity of the second capacitor 13 is denoted as capacity C2, and the capacity of the capacitor A realized by the first capacitor 12 and the second capacitor 13 is denoted as capacity C. Accordingly, the capacity C of the capacitor A is equal to the sum of the capacity C1 and the capacity C2.

According to the present embodiment, when the capacity C1 of the first capacitor 12 is less than the desired capacity, the first capacitor 12 and the second capacitor 13 are connected in parallel so that the capacity C of the capacitor A may fall within the desired capacity.

For example, in a case where the desired capacity is 9-11 pF, the capacity C1 of the first capacitor 12 is 8 pF, and the capacity C2 of the second capacitor 13 is 2 pF, the capacity C of the capacitor A may be 10 pF by connecting the first capacitor 12 and the second capacitor 13 in parallel so that the capacity C of the capacitor A may be adjusted to fall within the desired capacity. In this case, the area of the upper electrode 23 of the second capacitor 13 is preferably arranged to be 5-20% of the area of the upper electrode 21 of the first capacitor 12.

The distance L between the first capacitor 12 and the second capacitor 13 is preferably within 30-200 μm. It is noted that when the distance L between the first capacitor 12 and the second capacitor 13 is less than 30 μm, the first capacitor 12 and the second capacitor 13 may be short-circuited so that difficulties may arise upon forming the dielectric layers 19 and 22. When the distance L between the first capacitor 12 and the second capacitor 13 is greater than 200 μm, the first capacitor 12 and the second capacitor 13 may each comprise independent capacitors. Also, when the distance L is greater than 200 μm, the length of the wiring 17 has to be increased to thereby require more space for accommodating the wiring 17.

As can be appreciated from the above descriptions, the substrate according to the present embodiment includes the first capacitor 12 arranged on the base material 11 and the second capacitor 13 arranged on the base material 11 near the first capacitor 12, the second capacitor being realized by the lower electrode 18 that is held in common with the first capacitor 12, the dielectric layer 22, and the upper electrode 23 that has a smaller area than the upper electrode 21 of the first capacitor 12. When the capacity C1 of the first capacitor 12 is smaller than the desired capacity, the first capacitor 12 is connected in parallel with the second capacitor 13 so that the first capacitor 12 and the second capacitor 13 may comprise a single capacitor A and the capacity C of the capacitor A (i.e., sum of capacity C1 and capacity C2) may be easily adjusted to fall within the desired capacity (i.e., predetermined capacity value range for a capacitor to be of fair quality).

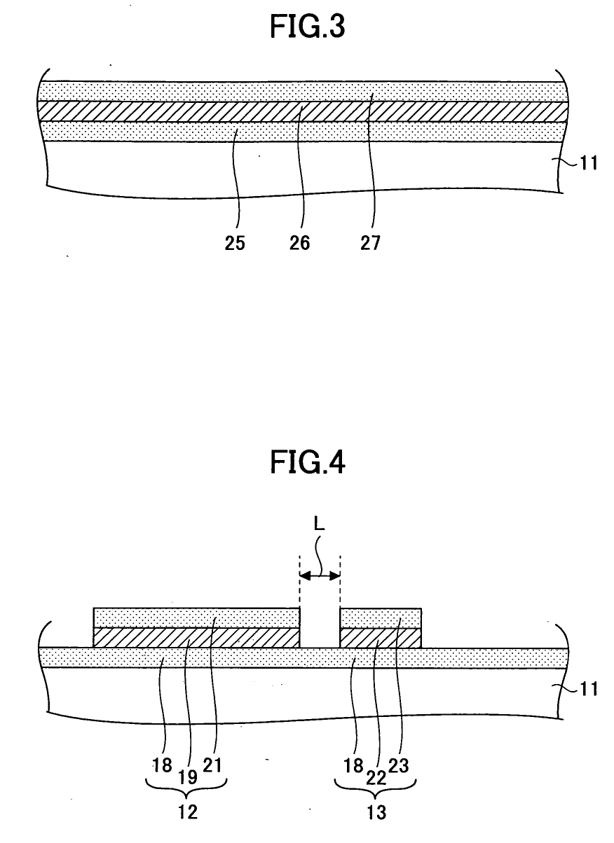

FIGS. 3-10 are diagrams showing process steps for manufacturing the substrate 10 of the present embodiment. It is noted that in these drawings, component parts that are identical to those of the substrate 10 described in relation to FIGS. 1 and 2 are given the same reference numerals.

In the following, a method for manufacturing the substrate 10 according to an embodiment of the present invention is described with reference to FIGS. 3-10.

First, in the process step illustrated in FIG. 3, a lower electrode layer 25, a dielectric layer 26, and an upper electrode layer 27 are deposited on the base material 11 in this order.

Specifically, a Cu plating with a thickness of 3-70 μm may be used as the lower electrode layer 25, for example. Then, resin including a BaTiO₃ filler with a thickness of 3-50 μm may be applied as the dielectric layer 26 through screen printing, for example. Then, a Cu film with a thickness of 3-70 μm may be arranged as the upper electrode layer 27 through sputtering, for example.

It is noted that the lower electrode layer 25 is patterned to realize the lower electrode 18, and the dielectric layer 26 is patterned to realize the dielectric layers 19 and 22. The upper electrode layer 27 is patterned to realize the upper electrodes 21 and 23.

In the process step illustrated in FIG. 4, the deposited lower electrode layer 25, dielectric layer 26, and upper electrode layer 27 are patterned so that the first capacitor 12 and the second capacitor 13 are formed (first and second capacitor forming step) Specifically, the first capacitor 12 is realized by the lower electrode 18, the dielectric layer 19, and the upper electrode 21; and the second capacitor 13 is realized by the lower electrode 18, the dielectric layer 22, and the upper electrode 23.

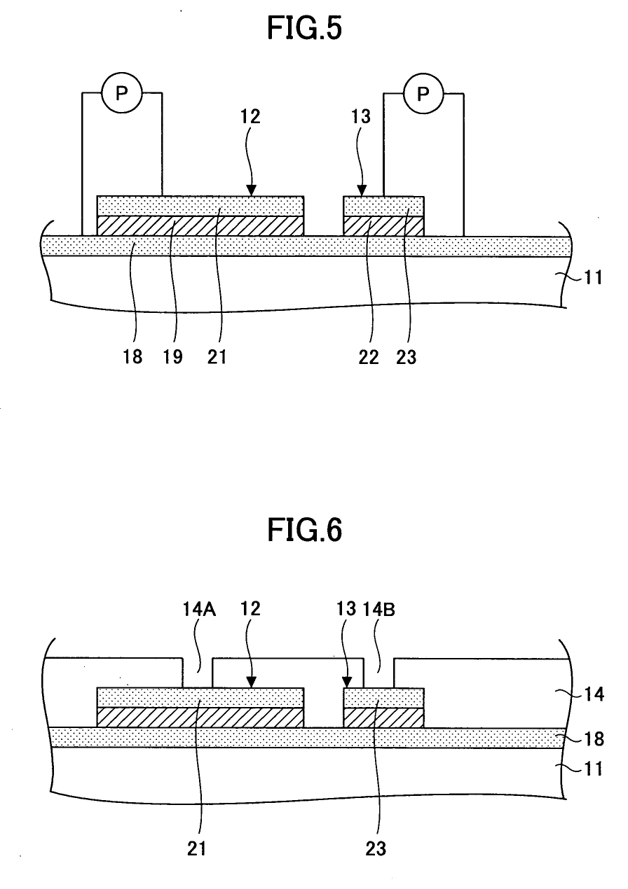

In the process step illustrated in FIG. 5, the capacity C1 of the first capacitor 12 and the capacity C2 of the second capacitor 13 are measured using a probe (capacity measuring step). In this process step, determinations are made as to whether the capacity C1 of the first capacitor 12 falls within the desired capacity, whether the capacity C1 is less than the desired capacity in a case where the capacity C1 does not fall within the desired capacity, whether the sum of the capacity C1 and the capacity C2 falls within the desired capacity in a case where the capacity C1 is less than the desired capacity, and whether to realize parallel connection between the first capacitor 12 and the second capacitor 13.

In the case of realizing parallel connection between the first capacitor 12 and the second capacitor 13, the position of the first capacitor 12 that requires capacity adjustment is identified by determining its coordinates, and data indicating whether to create the opening 14B are automatically generated. Such data may be generated for each set of plural substrates 10 according to a preferred embodiment.

It is noted that the process steps illustrated in FIGS. 6-10 correspond to steps for manufacturing the substrate 10 in a case where the capacity C1 of the first capacitor 12 is less than the desired capacity and the sum of the capacity C1 and the capacity C2 falls within the desired capacity.

In the process step illustrated in FIG. 6, the resin layer 14 is arranged to cover the first and second capacitors 12 and 13, expose the upper electrode 21 through the opening 14A, and expose the upper electrode 23 through the opening 14B.

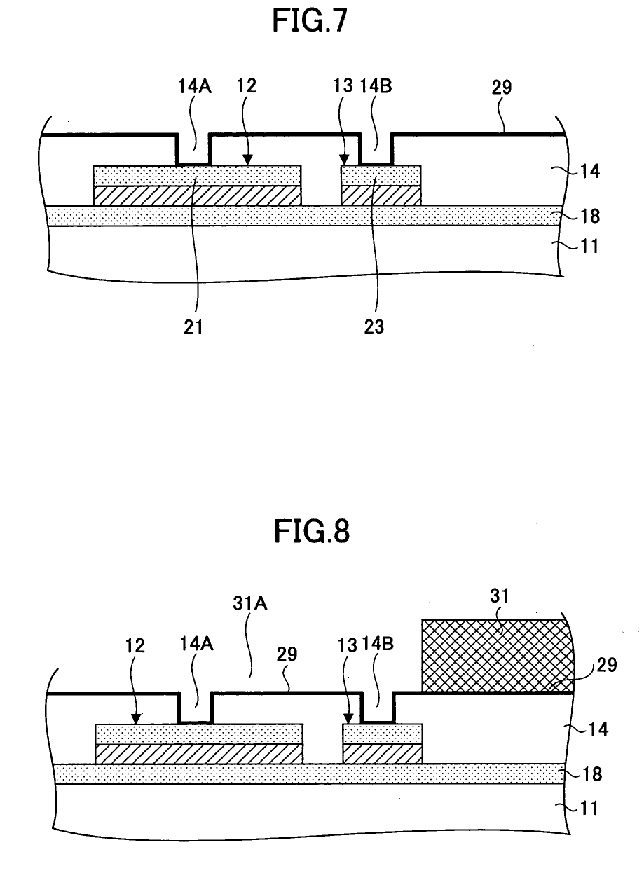

In the process step illustrated in FIG. 7, a seed layer 29 is arranged on the upper face of the structure shown in FIG. 6. It is noted that a Cu layer formed through non-electroplating may be used as the seed layer 29, for example.

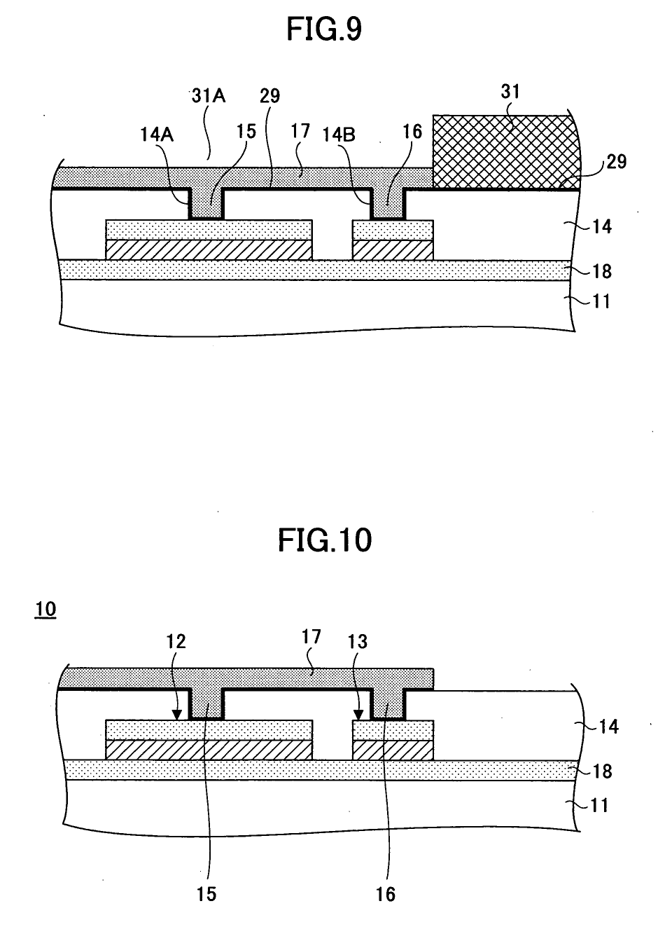

In the process step illustrated in FIG. 8, a resist film 31 having an opening 31A that corresponds to the shape of the wiring 17 is arranged on the seed layer 29. Then, in the process step illustrated in FIG. 9, a conductive material is arranged to fill the openings 14A and 14B, and cover the seed layer 29 that is exposed through the opening 31A to thereby form the vias 15, 16, and the wiring 17 at the same time. The conductive material realizing the vias 15, 16, and the wiring 17 may be Cu formed through electroplating, for example.

In the process step illustrated in FIG. 10, the resist layer 31 is removed and the seed layer 29 that has been covered by the resist layer 31 is removed thereafter so that the first capacitor 12 and the second capacitor 13 are connected in parallel to thereby realize the substrate 10 (capacitor connecting step).

It is noted that by using the substrate manufacturing method according to the present embodiment, the capacity C of the capacitor A that is made up of the first capacitor 12 and the second capacitor 13 may be easily adjusted to fall within the desired capacity without damaging the first capacitor 12. Also, the substrate 10 may be manufactured in a shorter period of time compared to a case in which the capacity C1 of the first capacitor 12 is adjusted through laser trimming, and as a consequence, productivity of the substrate may be improved.

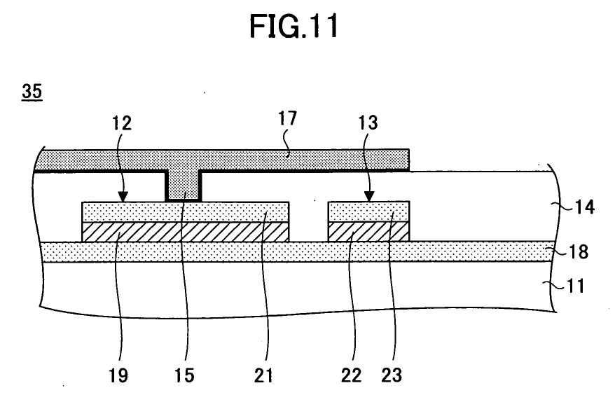

FIG. 11 is a cross-sectional diagram showing a substrate in which the first capacitor and the second capacitor are not connected in parallel. It is noted that component parts of the substrate 35 shown in FIG. 11 that are identical to those of the substrate 10 described in relation to FIG. 1 are given the same reference numerals.

In a case where the capacity C1 of the first substrate 12 falls within the desired capacity, or in a case where the sum of the capacity C1 and the capacity C2 is greater than the desired capacity, only the opening 14A is created in the resin layer 14 in a process step of forming the resin layer 14 corresponding to the process step of FIG. 6. Then, process steps similar to those illustrated in FIGS. 7-10 are performed to manufacture the substrate 35 shown in FIG. 11

Further, it is noted that the present invention is not limited to the specific embodiments described above, and variations and modifications may be made without departing from the scope of the present invention.

The present application is based on and claims the benefit of the earlier filing date of Japanese Patent Application No. 2005-195161 filed on Jul. 4, 2005, the entire contents of which are hereby incorporated by reference.

What is claimed is:

1. A substrate comprising:
a base material;
a first capacitor arranged on the base material, the first capacitor being realized by a lower electrode, a first dielectric layer, and a first upper electrode; and
a second capacitor arranged on the base material near the first capacitor, the second capacitor being realized by the lower electrode that is held in common with the first capacitor, a second dielectric layer, and a second upper electrode having a second area that is smaller than a first area of the first upper electrode;
wherein, the first capacitor and the second capacitor are connected in parallel in a case where a capacity of the first capacitor is less than a desired capacity.

2. The substrate as claimed in claim 1, wherein
a distance between the first capacitor and the second capacitor is 30-200 μm.

3. A method for manufacturing a substrate that includes a base material, a first capacitor arranged on the base material, and a second capacitor arranged on the base material near the first capacitor, the first capacitor being realized by a lower electrode, a first dielectric layer, and a first upper electrode, and the second capacitor being realized by the lower electrode that is held in common with the first capacitor, a second dielectric layer, and a second upper electrode having a second area that is smaller than a first area of the first upper electrode, the method comprising:
a first and second capacitor forming step involving simultaneously forming the first capacitor and the second capacitor on the base material;
a capacity measuring step involving measuring a first capacity of the first capacitor and a second capacity of the second capacitor; and
a capacitor connecting step involving connecting the first capacitor and the second capacitor in parallel in a case where the first capacity of the first capacitor is less than a desired capacity.
